(19) United States
(12) Patent Application Publication
(10) Pub. No.: US 2010/0072615 A1
(43) Pub. Date: Mar. 25, 2010

(54) High-Electrical-Current Wafer Level Packaging, High-Electrical-Current WLP Electronic Devices, and Methods of Manufacture Thereof

(75) Inventors: Arkadii V. Samoilov, Saratoga, CA (US); Duane Thomas Wilcoxen, Dallas, TX (US); Viren V. Khandekar, Flower Mound, TX (US); Vivek Jain, Cupertino, CA (US); Ahmad R. Ashrafzadeh, Morgan Hill, CA (US); Mansour Izadinia, Cupertino, CA (US)

Correspondence Address: MAXIM/BSTZ;Blakely Sokoloff Taylor & Zafman LLP, 1279 OAKMEAD PARKWAY, SUNNYVALE, CA, 94085-4040, US

(73) Assignee: MAXIM INTEGRATED PRODUCTS, INC., Sunnyvale, CA (US)

(21) Appl. No.: 12/237,078

(22) Filed: Sep. 24, 2008

(51) Int. Cl. H01L 23/48

(52) U.S. Cl. 257/737; 257/E21.507; 257/E23.068

(57) ABSTRACT

The present invention has various aspects relating to the maximization of current carrying capacity of wafer level packaged chip scale solder pad mounted integrated circuits. In one aspect, the solder pad areas are maximized by using rectangular solder pads spaced as close together as reliable mounting to a circuit board will allow. In another aspect, multiple contact pads may be used for increasing the current capacity without using contact pads of different areas. In still another aspect, vias are used to directly connect one lead of high current component or components to a contact pad directly above that component, and to route a second lead of the high current component to an adjacent contact pad by way of a thick metal interconnect layer.

### BACKGROUND OF THE INVENTION

1. Field of the Invention

The present invention relates to the field of packaging of high current semiconductor devices and integrated circuits.

2. Prior Art

As integrated circuits become smaller and more complex, packaging becomes a substantial problem, both in terms of size and cost. Classically an integrated circuit wafer is diced, and each individual die is mounted on a respective lead frame having a plurality of leads integrally connected at their outer ends. Then each contact pad on the integrated circuit is wire bonded to a respective lead on the lead frame, and the integrated circuit and wire bonds are encapsulated in a suitable resin. Finally the leads on the lead frame are trimmed to electrically separate the leads, and the leads are bent to their final shape.

An increasing number of end products cannot tolerate the size of integrated circuits packaged in this manner, because of the size of the package, because of the number of leads required, or both. As a result, smaller packages have been developed, such as surface mount packages. While various such packages are currently in use, in general such packages have solder contacts on their mounting surface, typically with a solder ball on each contact, so that on placement of the surface mount package on a circuit board and heating, the solder will flow and wet the circuit board and contact, thereby physically and electrically connecting the integrated circuit to the board.

More recently, the individual die themselves have been solder ball mounted as described above. In such mounting, contact pads on the integrated circuit are exposed through circular openings in the insulative layer or layers on the integrated circuit, to each of which a solder ball is attached. The mounting surface of such die is shown schematically in FIG. 1. Such packaging may be done as wafer level packaging, with the wafer being diced as a last or near last step in the fabrication process.

### BRIEF DESCRIPTION OF THE DRAWINGS

FIG. 1 is a schematic view of the mounting surface of a prior art chip scale solder pad mounted integrated circuit.

FIG. 2 is a schematic view of the mounting surface of a chip scale solder pad mounted integrated circuit in accordance with one aspect of the present invention

FIG. 3 is a schematic illustration of parts of an integrated circuit, specifically illustrating the planform of the electrical connections to an exemplary contact pad.

FIG. 4 is a schematic cross section taken along line 4-4 of FIG. 3.

FIG. 5 is a schematic cross section taken along line 5-5 of FIG. 3.

FIG. 6 is a schematic cross section taken along line 6-6 of FIG. 3.

### DETAILED DESCRIPTION OF THE PREFERRED EMBODIMENTS

The present invention is related to a method of fabricating an integrated circuit using wafer level packaging (WLP) for high electrical current capabilities in a way that is less expensive than other methods. In particular, the invention utilizes soldering alloys on the chip to create an electrical contact of a sufficiently large area to maximize the allowable electrical current per pin. The invention further accomplishes high current capabilities using a wafer-level chip-size packaging, which results in a low cost and small form-factor.

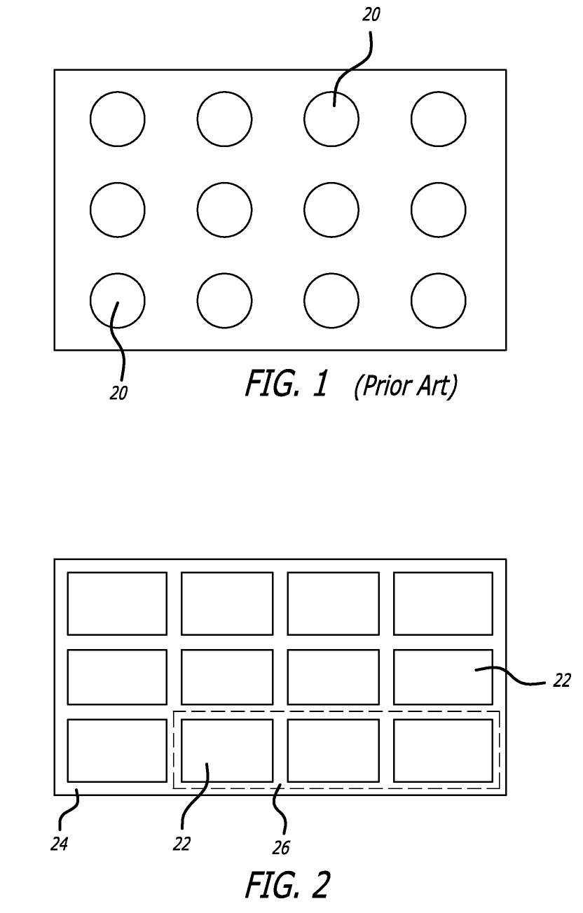

FIG. 2 illustrates one aspect of the present invention. In comparison to FIG. 1, FIG. 2 uses contact pads 22 on the integrated circuit 24 that are exposed through rectangular openings in the passivation and insulation layers. It has been found that use of a solder ball does not inherently require the use of a circular contact pad, as a solder ball will flow against its own surface tension to wet an area of substantially any reasonable shape. Assuming that the circular openings of the prior art were spaced as close together as possible, square pads similarly spaced will have an area of 4/π times the area of the circular pad, an over 27% gain in contact area. Rectangular pads as shown in FIG. 2 will exhibit an even greater gain in contact area, and in the example shown, in a smaller planform.

Another feature of the present invention is the use of multiple contact pads 22 for connections requiring high current capacity. Use of multiple contact pads 22 on the integrated circuit 24 rather than a single large pad is preferred, as multiple pads, all of the same area, can conveniently fall within an array of multiple pads, more easily facilitating placement of the solder balls, and better assuring the right amount of solder is available per contact pad, as opposed to too much or too little, either of which could lead to difficulties during soldering to a circuit board. It also reduces stress on the substrate. Such a connection is also illustrated in FIG. 2, in this case forming an array of equal area, same shape pads, though same shape or regular array are not limitations of the invention. As shown therein, a patterned thick conductive layer 26 (usually, but not always thicker than the lower interconnect layers), typically aluminum or copper, is provided spanning multiple pads 20 and exposed in each of the multiple pad areas by openings in a passivation and insulation layers on the integrated circuit 24, though insulated between pads 22 by remaining parts of the passivation layer between pads, and typically a further dielectric layer over the passivation layer. The thick conductive layer 26 is connected to the high current device or devices by local vias within the integrated circuit, the devices preferably being directly under or very close to the thick conductive layer 26.

In the foregoing embodiment, an opening is created in the passivation layer over an underlying thick conductive layer 26 to create an electrical connection from a printed circuit board (PCB) of an electronic device. This opening should be of a sufficiently large area to be capable of carrying a targeted electrical current. This passivation opening is covered with a solder alloy material that is re-flown post deposition, in order to provide a low-resistance, high-mechanical-robustness electrical connection to the PCB. The solder may be screen-printed to the contact pads by distributing a solder paste over the wafer. Alternatively, solder may be electroplated. Alternatively, pre-formed solid solder objects, typically spheres (balls), can be dropped onto the wafer in the loci of the passivation openings.

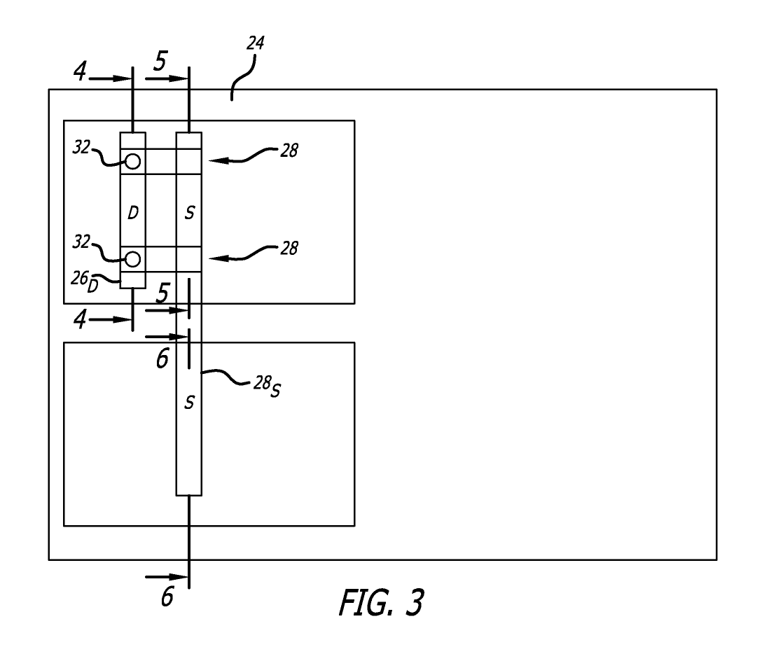

In accordance with another aspect of the present invention, FIG. 3 schematically illustrates a top view of portions of an integrated circuit 24 having two high current MOS devices 28 coupled in parallel (which may have separately controlled gates, not shown). Each MOS device has a drain connection D and a source connection S. As shown therein, each drain has a thick, typically aluminum conductive layer 26_{D} coupled through vias 32 to a copper (or aluminum for example) pad defining the size of the solder pad. The thick conductive layer 26_{D} may span more than one contact pad, as the thick conductive layer 26 of FIG. 2. The sources are also connected to a thick conductive layer 2_{S}, typically connected to a neighboring contact pad to minimize the resistance from the high current MOS devices to the contact pads. Thick conductive layers 26_{S} and 26_{D} are part of a single thick conductive layer before that layer is patterned.

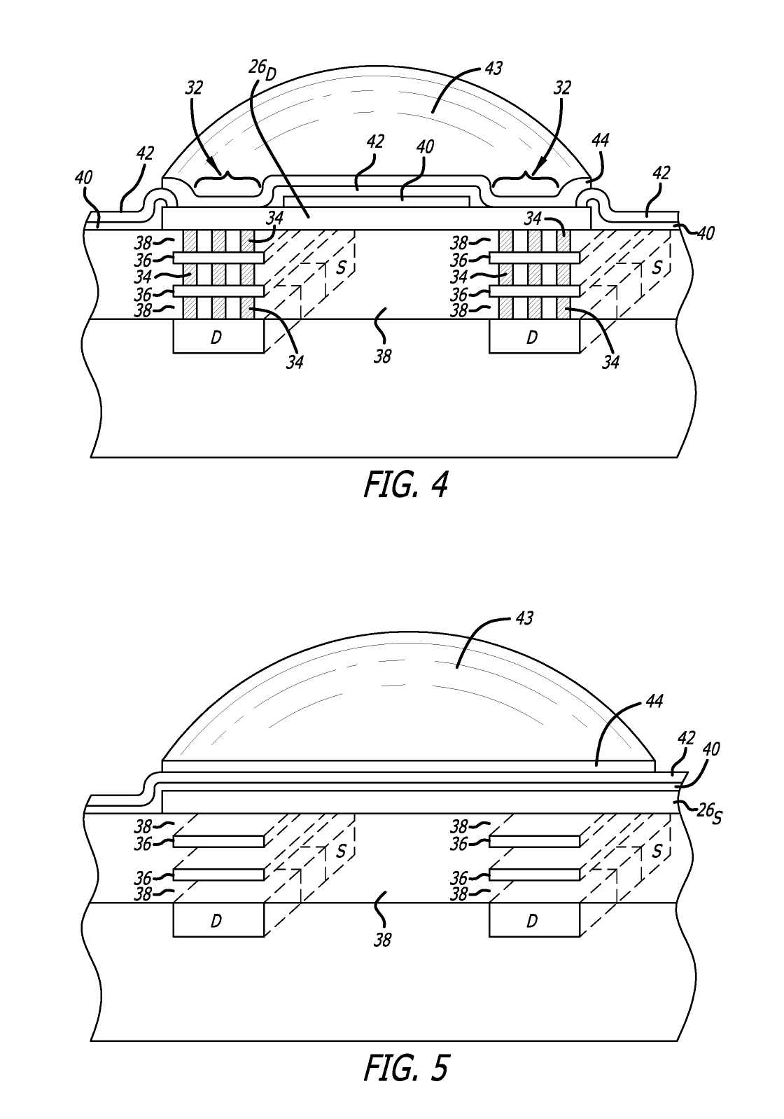

Schematic cross sections taken along lines 4-4, 5-5 and 6-6 of FIG. 3 are presented in FIGS. 4, 5 and 6 respectively. As may be seen in FIG. 4, and as is common in integrated circuits, there typically are multiple metal interconnect layers 36 over the individual devices themselves, the interconnect layers being separated by insulation layers 38, with local vias 34 in the insulation layers to make contact with the integrated circuit devices as required. There may be other parts of the interconnect layers or even other devices between the devices, not shown. In accordance with this aspect of the present invention, local vias 34 are formed in the insulation layers and filled with a conductor, so as to form a conductive stack directly from the drain area through local areas of the interconnect layers 36 to a (patterned) thick conductive layer 26_{D} and 26_{S} (FIG. 3). The interconnect layers 36 may be aluminum, in which case the openings in the insulation layers may be filled with tungsten (30). If copper is used for the interconnect layers 36, the openings in the insulation layers for the local vias 34 may be copper filled. Once the interconnect layers 36 are completed and covered with an insulation layer and the local vias 34 are completed, the thick conductive layer 26_{D} and 26_{S} is deposited and patterned, and then covered by a passivation layer 40 and insulative layer 42, such as a polyimide. For creating the solder bumps 43, openings are formed in the final passivation layer 40 and insulation layer 42 over the conductive stack connected to the drain to expose the thick conductive layer 26_{D}, and a copper redistribution layer 44 is deposited and patterned to define the contact pad area. The final step is to apply the solder 43 using any of the techniques previously discussed.

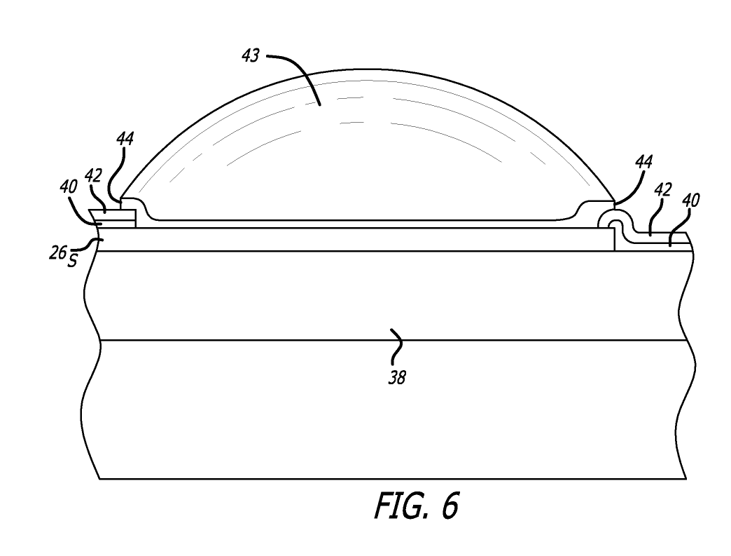

For the source contact in this example (FIGS. 5 and 6), the (patterned) thick conductive layer 26_{S} remains insulated from the copper (or aluminum) redistribution layer 44, and is routed to an adjacent contact pad, as shown in FIGS. 3 and 6, and connected to a redistribution layer 44 of the adjacent contact pad through corresponding openings in the passivation layer 40 and final insulation layer 42 (FIG. 6). No integrated circuit devices are shown in FIG. 6, though multiple devices and multiple interconnect layers would normally be present.

Of course the devices illustrated are exemplary only. In other examples, there may only be one high current device on the integrated circuit, or multiple high current devices connected differently. By way of example, in many switching converters and motor drives having on-chip drive transistors, high current high side and low side transistor switches may be connected in series and alternately operated. In this case, there will be three high current contacts needed, each of which in accordance with the present invention may preferably use one (or more) of three adjacent contact pads. If more than one contact pad is used for each contact, preferably the three contacts are brought out on three adjacent contact pads aligned in a first direction (say in the x direction), with the additional contact pads for each contact being aligned in a second direction (the y direction). Centering the multiple contacts as a group with respect to each high current device to the extent possible further reduces the resistance of the current path from the contact to the high current device through the thick interconnect layer. In that regard, all aspects of the present invention are directed to minimize the i²R loses between a circuit board on which the integrated circuit may be mounted and the device in the integrated circuit so as to minimize the heat generated beyond that generated by the device itself, thereby allowing the device to operate at the highest current possible for the cooling capacity of the chip scale package and its mounting. In the case of high side and low side transistor switches alternately operated, the center contact will have a higher duty cycle than the other two contacts, and thus may be connected to more contact pads than the other two contacts.

Thus the present invention has a number of aspects, which aspects may be practiced alone or in various combinations or sub-combinations, as desired. While a preferred embodiment of the present invention has been disclosed and described herein for purposes of illustration and not for purposes of limitation, it will be understood by those skilled in the art that various changes in form and detail may be made therein without departing from the spirit and scope of the invention as defined by the full breadth of the following claims.

What is claimed is:

1. A chip scale integrated circuit comprising:
an integrated circuit having a plurality of solder bumps on a surface thereof for reflowing to mount the integrated circuit to a circuit board;
the solder bumps being configured to reflow to a pattern of rectangular solder contacts.

2. The chip scale integrated circuit of claim 1 further comprised of a thick conductive layer electrically coupled to a plurality of the solder bumps so that the plurality of solder bumps electrically act as a single solder bump.

3. The chip scale integrated circuit of claim 2 wherein all the solder bumps are the same area.

4. The chip scale integrated circuit of claim 2 wherein the conductive layer is insulated from interconnect layers of the integrated circuit, and is electrically connected through vias to at least one device of the integrated circuit.

5. The chip scale integrated circuit of claim 4 wherein the conductive layer is connected to a second conductive layer underneath through an opening in a dielectric between the two conductive layers, the second conductive layer being connected to interconnect layers of the integrated circuit through interconnect vias.

6. The chip scale integrated circuit of claim 5 wherein the interconnect layers are aluminum layers and the vias are filled with tungsten.

7. The chip scale integrated circuit of claim 5 wherein the interconnect layers are copper layers and the vias are filled with copper.

8. The chip scale integrated circuit of claim 5 wherein the openings in the dielectric between the two conductive layers are underneath a solder bump.

9. The chip scale integrated circuit of claim 2 wherein the conductive layer is aluminum.

10. The chip scale integrated circuit of claim 2 wherein the conductive layer is copper.
